(19) United States
(12) Patent Application Publication
(10) Pub. No.: US 2008/0157170 A1
(43) Pub. Date: Jul. 3, 2008

(54) EEPROM CELL WITH ADJUSTABLE BARRIER IN THE TUNNEL WINDOW REGION

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/618,165

(22) Filed: Dec. 29, 2006

(51) Int. Cl. H01L 29/788; H01L 21/336

(52) U.S. Cl. 257/321; 438/264; 257/E21.422; 257/E29.3

(57) ABSTRACT

An electrically programmable memory cell and corresponding method for fabricating the same, provide a reduced electron tunneling threshold to reduce parasitic substrate currents during cell programming. A floating gate of the cell is formed over an injector dopant region diffused within and encompassed by a first dopant region. Both dopant regions are situated beneath a self-aligned tunneling window of the floating gate. The dopant regions are each high concentration dopants and of complementary species to one another. The injector dopant region produces an increase in surface potential that lowers a tunneling barrier height and produces the lower electron tunneling threshold.

### TECHNICAL FIELD

The present invention relates to non-volatile memory cells and memory arrays and, in particular, to fabrication of an apparatus and a method of fabricating non-volatile memory devices with reduced parasitic substrate current during programming.

### BACKGROUND ART

A non-volatile memory device retains data even after electrical power to the device is terminated. One particular type of non-volatile memory device is an electrically erasable programmable read only memory (EEPROM) device. In an EEPROM device, programming and erasing are accomplished by transferring electrons to and from a floating gate electrode through a thin dielectric layer, known as a tunnel-oxide layer, located between the floating gate electrode and an underlying substrate. Typically, electron transfer is carried out by either hot electron injection or by Fowler-Nordheim tunneling. In either electron transfer mechanism, a voltage is coupled to the floating gate electrode by a control gate electrode, also known as a programming region. The control gate electrode or programming region is capacitively coupled to the floating gate electrode such that a voltage applied to the programming region is coupled to the floating gate electrode.

With reference to FIG. 1, a tunnel oxide window 110 is produced within a gate oxide layer 105 in a prior art semiconductor cross-section diagram 100. A buried layer of high concentration n-type dopant 115 (BN+) is produced within a lightly doped p-type substrate 118 (P-SUBS) beneath the tunnel oxide window 110. The formation of the tunnel oxide window 110 and the buried n-type dopant layer 115 are typical of a tunnel diode window within an EEPROM cell.

An energy diagram 101, corresponding to the prior art semiconductor cross-section diagram 100, has a donor dopant concentration 120 (N_{D}) extending latterly and corresponding with an extent of the buried n-type dopant layer 115. An acceptor dopant concentration 125 (N_{A}) extends latterly from a position corresponding to an edge of the buried n-type dopant layer 115.

A surface potential diagram 103, corresponding to the semiconductor cross-section diagram 100, has a surface potential 130 (Ψ_{S}) commencing from a low level beneath the tunnel oxide window 110. The surface potential 130 continues laterally through a continuous transition at the boundary of the buried n-type dopant layer to a higher potential corresponding to the surface of the p-type substrate 118.

The elevated voltages needed to operate an EEPROM cell during programming require high-voltage devices which increase production costs. It would be highly desirable to have a means for lowering a threshold of the tunneling electrons during programming in order to reduce the need for high-voltage devices.

### SUMMARY

A method of fabricating an electronic integrated circuit device on a first surface of a substrate, the method is comprised of forming a first dielectric film layer over the first surface of the substrate; forming at least one further dielectric film layer over the first dielectric and creating a first aperture in the at least one further dielectric film layer, the first aperture having sidewalls that are non-parallel to the first surface of the substrate; etching a portion of the first dielectric film layer underlying the first aperture to form a tunneling window; creating a first dopant region formed substantially within an upper portion of the substrate underlying the first aperture; forming spacers on the sidewalls of the first aperture such that a distance between spacers on opposing sidewalls of the first aperture is less than a limit of optical photolithography, the opposing spacers thus forming a second aperture; and creating a second dopant region formed substantially within an upper portion of the substrate underlying the second aperture, the second dopant region being self-aligned with the second aperture.

A method of fabricating an electronic integrated circuit device, comprising: providing a substrate, the substrate being substantially comprised of silicon and having a first surface; forming a first dielectric film layer over the first surface of the substrate; forming at least one further dielectric film layer over the first dielectric film layer and creating a first aperture in the at least one further dielectric film layer, the first aperture having sidewalls that are non-parallel to the first surface of the substrate; etching a portion of the first dielectric film layer underlying the first aperture thus forming a tunneling window; creating a first dopant region formed substantially within an upper portion of the substrate underlying the first aperture; forming a spacer film layer over the at least one further dielectric film layer and a portion of the first dielectric film layer underlying the first aperture; etching regions of the spacer film layer that are essentially parallel to the first surface of the substrate while leaving regions of the spacer film layer that are essentially perpendicular to the first surface of the substrate, to create spacers on the sidewalls of the first aperture, a distance between spacers on opposing sidewalls of the first aperture being less than a limit of optical photolithography, a second aperture formed by the opposing spacers; and creating a second dopant region formed substantially within a portion of the substrate underlying the second aperture and within the first dopant region, the second dopant region being self-aligned with the second aperture.

A memory device, comprising: a floating gate forming a portion of the memory device, the floating gate being comprised substantially of a first semiconducting material and being constructed over a substrate; a gate dielectric material interposed between the floating gate and a first surface of the substrate; a recess etched in an upper portion of the gate dielectric material to form a tunneling window; a first dopant region formed in relationship to the tunneling window substantially within an upper portion of the substrate and underlying a portion of the floating gate; a spacer region formed on the sidewalls of the first aperture such that a distance between spacers on opposing sidewalls of the first aperture is less than a limit of optical photolithography, the opposing spacers thus forming a second aperture; and an injector dopant region disposed in close proximity to and self-aligned with the second aperture, the injector dopant region encompassed by the first dopant region.

### BRIEF DESCRIPTION OF DRAWINGS

FIG. 1 is a semiconductor cross-section of a prior art gate oxide tunnel window above a buried n-type dopant region with corresponding energy and surface potential diagrams.

FIG. 2A is a semiconductor cross-section of an EEPROM cell with an exemplary nitride layer applied to an ONO structure of the present invention.

FIG. 2B is a semiconductor cross-section of an etched portion of a resist layer applied to the structure of FIG. 2A.

FIG. 2C is a semiconductor cross-section of an etched tunnel window opening on the structure of FIG. 2B.

FIG. 2D is a semiconductor cross-section of an exemplary buried n-type dopant region beneath a tunnel window opening of the present invention.

FIG. 2E is a semiconductor cross-section of nitride spacers in a tunnel window opening of the structure of FIG. 2D.

FIG. 2F is a semiconductor cross-section of an exemplary p+ region beneath the tunnel window of FIG. 2E.

FIG. 3 is a semiconductor cross-section of an EEPROM cell with a p+ dopant region beneath a tunnel window.

FIG.4 is a semiconductor cross-section of an exemplary p+ region beneath a gate oxide tunnel window with corresponding energy and surface potential diagrams.

### DETAILED DESCRIPTION

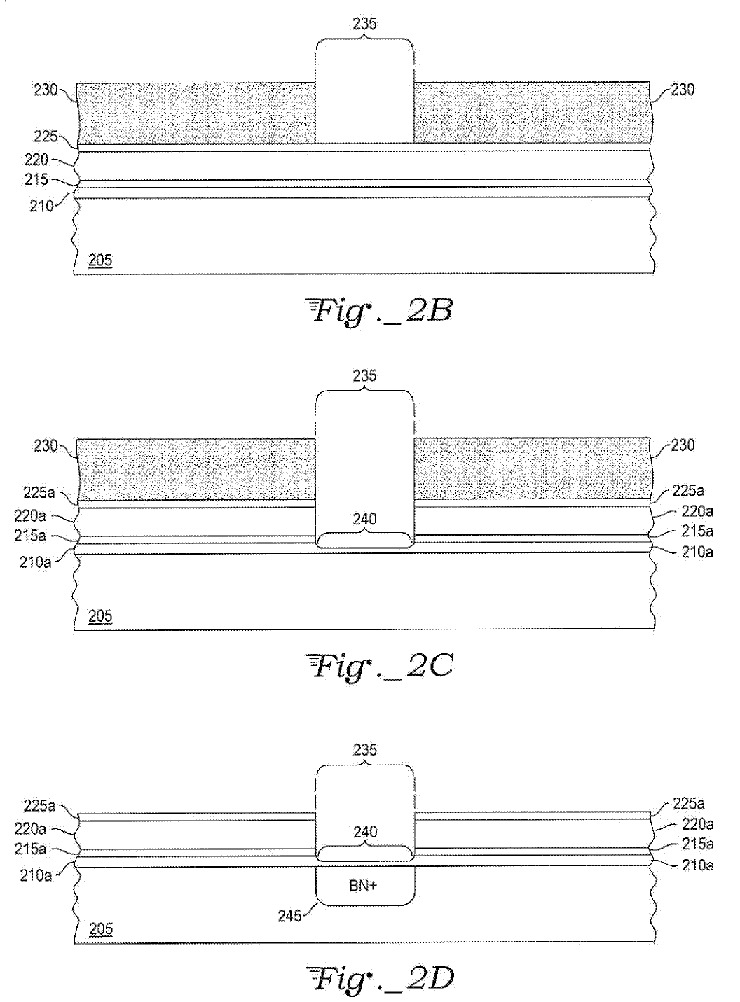

With reference to FIG. 2a, an exemplary starting cross-section of the present invention includes a substrate 205, a first dielectric layer 210, a second dielectric layer 215, a third dielectric layer 220, and a fourth dialectric layer 225. The semiconductor substrate 205 may be, for example, substantially a lightly doped p-type starting material of silicon. In a specific exemplary embodiment, the substrate 205 is a p-type silicon wafer (or alternatively, a p-type well in a substrate). The semiconductor substrate 205 may be comprised of various materials known in the semiconductor art. Such materials include silicon (or other group IV materials), compound semiconductors (e.g., compounds of elements, especially elements from periodic table groups III-V and II-VI), quartz reticles, or other suitable materials.

The first dialectric layer 210 is, for example, approximately 200 Angstrom (Å) continuous layer disposed on an upper-most surface of the semiconductor substrate 205. The first dielectric layer 210 may vary in thickness from about 100-300 Å. The first dialectic layer 210 is, for example, substantially a high quality thermally grown silicon dioxide which may be produced by a chemical vapor deposition (CVD) process. Alternatively, the first dialectic layer 210 may be produced by any of a variety of techniques such as atomic layer deposition (ALD), chemical vapor deposition (CVD), low-pressure CVD (LPCVD), high-density plasma chemical vapor deposition (HDP-CVD), plasma-enhanced CVD (PECVD), or plasma-assisted CVD (PACVD).

In this specific exemplary embodiment, the second dielectric layer 215 is an 80 Å layer of a nitride, for example, silicon nitride (Si₃N₄). The third dielectric layer 220 is substantially comprised of TEOS oxide (tetra-ethoxysilane or tetraethyl orthosilicate). The third dielectric layer 220 may be very, for example, from about 200-300 Å. An 80 Å layer of silicon nitride (Si₃N₄) substantially comprises the fourth dialetic layer 225. The second dielectric layer 215 and the fourth dialectic layer 225 may vary in thickness from about 60-100 Å.

With reference to FIG. 2B, a photoresist material is deposited on top of the fourth dialectric layer 225 and is processed to form a patterned photoresist layer 230. A first aperture is formed by the patterning of the patterned photoresist layer 230. The first aperture is produced at a minimum feature size capability of the photo lithographic process.

With reference to FIG. 2C, a selective etchant, such as a highly selective dry etch or wet chemical etch is chosen to etch a patterned fourth dielectric layer 225a, a patterned third dielectric layer 220a, a patterned second dielectric layer 215a, a first portion of a patterned first dialectic layer 210a, thus forming a first aperture 235. Etching of underlying layers can occur through various wet-etch techniques (e.g., the patterned first dielectric layer 210a may be etched in hydrofluoric acid, such as contained in a standard buffered oxide etch (BOE), or orthophosphoric acid) or dry etch techniques (e.g., reactive-ion-etching (RIE)).

A skilled artisan will recognize that various chemistries may be chosen which will readily etch, for example, a polysilicon layer while leaving a nitride layer essentially intact (or vice versa) or etch a nitride layer while leaving a silicon dioxide layer intact (or vice versa). Therefore, etches of one layer may be performed while leaving adjacent layers intact while avoiding tedious and critical timing steps. Layers comprised of materials dissimilar to the layer being etched thus serve as an etch stop. Such etching techniques are known in the semiconductor art.

With continued reference to FIG. 2C, etching of the first aperture 235 extends through the fourth, third, and second etched dielectric layers 225a, 220a, 215a. A further etching, for example by RIE, may be used with high resolution with respect to depth to etch a portion of the first dielectric layer 210. The resolution of the recess is provided by, for example, duration or energy of the ion etch. The recess thus forms a tunneling window 240.

With reference to FIG. 2D, the patterned photoresist layer 230 is removed. A first dopant region 245 is produced by applying a dopant within the first aperture 235 and substantially into the uppermost surface of the substrate 205 beneath the first aperture 235. The first dopant may be, for example a high concentration n-type dopant applied by ion implantation.

With reference to FIG. 2E, a blanket spacer dielectric layer (not shown) is formed for example, by CVD or LPCVD techniques. In a specific exemplary embodiment, the spacer dielectric layer is chosen to be chemically dissimilar to the underlying etched third dielectric layer 220a. For example, if the patterned third dielectric layer 220a is chosen to be TEOS oxide, then the spacer dielectric layer may be chosen to be silicon nitride. In this way, an etchant which is selective between silicon dioxide and silicon nitride allows the patterned third dielectric (e.g., TEOS oxide) layer 220a to act as an etch stop for etching the patterned fourth dielectric layer 225a. Selective etching of the patterned fourth dielectric layer 225a produces a spacer dielectric 250 from the spacer dielectric (e.g., silicon nitride) layer. The spacer dielectric 250 is formed on the first aperture sidewalls by a selective etchant. The selective etchant is used to etch the spacer dielectric 250 without substantially affecting the integrity of any other layer. Thus a second aperture 265 is produced by the substantially vertical inner walls of the spacer dielectric 250.

With reference to FIG. 2F, an injector dopant region 255 is produced by applying a second dopant within the second aperture 265 and into the uppermost surface of the substrate 205. The second dopant is diffused substantially within a portion of the substrate underlying the second aperture 265. The injector dopant region 255 is encompassed by the first dopant region 245. The second dopant may be, for example a high concentration p-type dopant applied by ion implantation. The implantation of the second dopant is self-aligned with the patterned third dielectric layer 220a and the spacer dielectric 250 formed previously. The second dopant is of a complementary type compared to the first dopant used in forming the first dopant region 245. A “width” of the spacer dielectric 250 is dependent upon a thickness of the deposited spacer dielectric layer and a step height of a proximate structure; the spacer dielectric 250 may be, for example, approximately 0.7·t, where “t”is the thickness of the combined thicknesses of the patterned third dielectric layer 220a and the patterned second dielectric layer 215a. Thus, the width of the spacers and, consequently any underlying features, may be fabricated to be extremely small. Therefore, the fabrication method described herein, and a device resulting from employing the method, may have components that are formed below a limit of resolution of optical photolithography by utilizing spacers to separate laterally displaced features (i.e., features that have spatial dimensions less than the limit of resolution in planes parallel to a face of a substrate or wafer, or “x-y” dimensions).

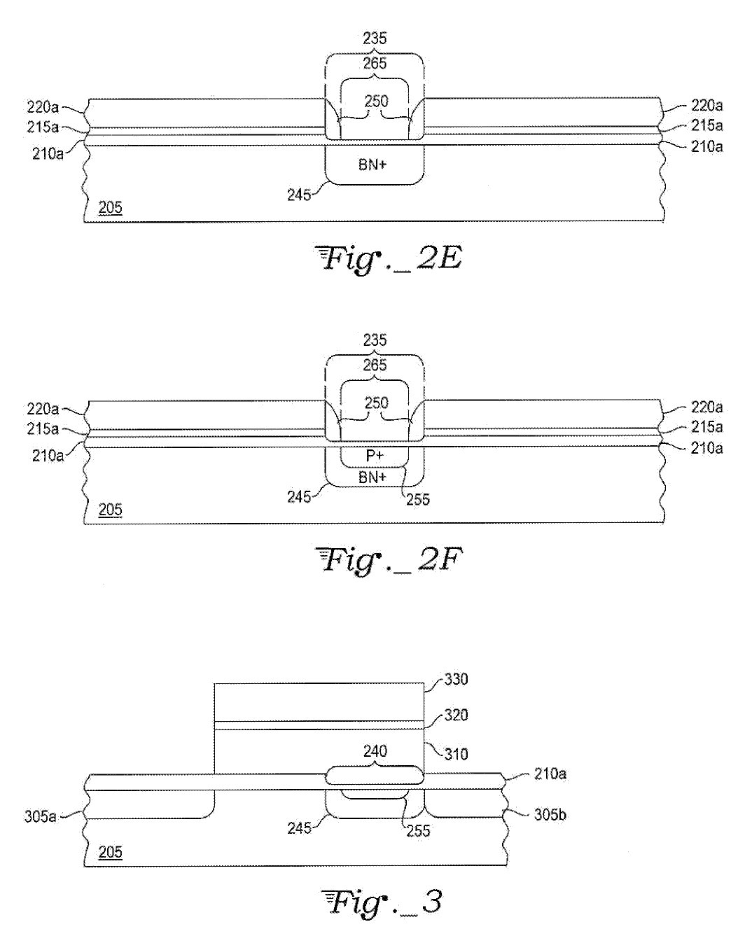

With reference to FIG. 3, the injector dopant region 255 and encompassing first dopant region 245 are situated beneath the tunneling window 240 of an EEPROM cell. The EEPROM cell has a floating gate 310, a sense gate 330, and an inter-grate dielectric 320. A source region 305a and a drain region 305b are diffused within the uppermost surface of the substrate 205. The drain region 305b adjoins an edge of the first dopant region 245 at the edge of the EEPROM gate structure formed by the edge of the floating gate 310. The source region 305a is formed at an opposite edge of the floating gate 310 and extends laterally at the surface of the substrate 205 away from an area beneath the floating gate 310. Thus a channel is formed from the source region 305a beneath the floating gate 310 to the first dopant region 245 and the drain region 305b. The floating gate 310 is disposed above the channel and the sense gate 330 covers the floating gate 310.

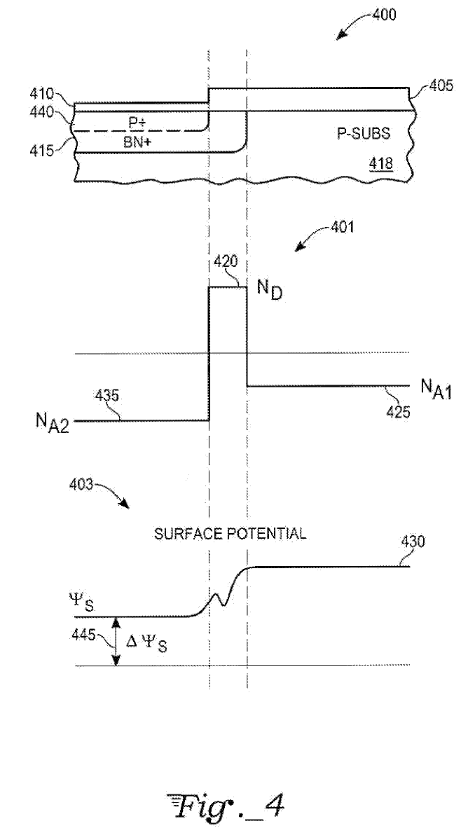

With reference to FIG. 4, in an exemplary semiconductor cross-section diagram 400, a tunnel oxide window 410 is produced within a gate oxide layer 405. A first dopant region 415 of high concentration n-type dopant is produced within a lightly doped p-type substrate 418 beneath the tunnel oxide window 410. An injector dopant region 440 is produced of high concentration p-type dopant beneath the tunnel oxide window 410 and within the first dopant region 415.

An energy diagram 401, corresponding to the semiconductor cross-section diagram 400, has a concentration level for a donor dopant 420 (N_{D}) extending latterly corresponding with an extent of an outer edge of the buried n-type dopant layer 415 at the surface of the semiconductor substrate 418. A concentration level for a substrate acceptor dopant 425 (N_{A1}) extends latterly from a position corresponding to an edge of the buried n-type dopant layer 415. A concentration level for an injector acceptor dopant 435 (N_{A2}) extends latterly from a position corresponding to an edge of the buried n-type dopant layer 415.

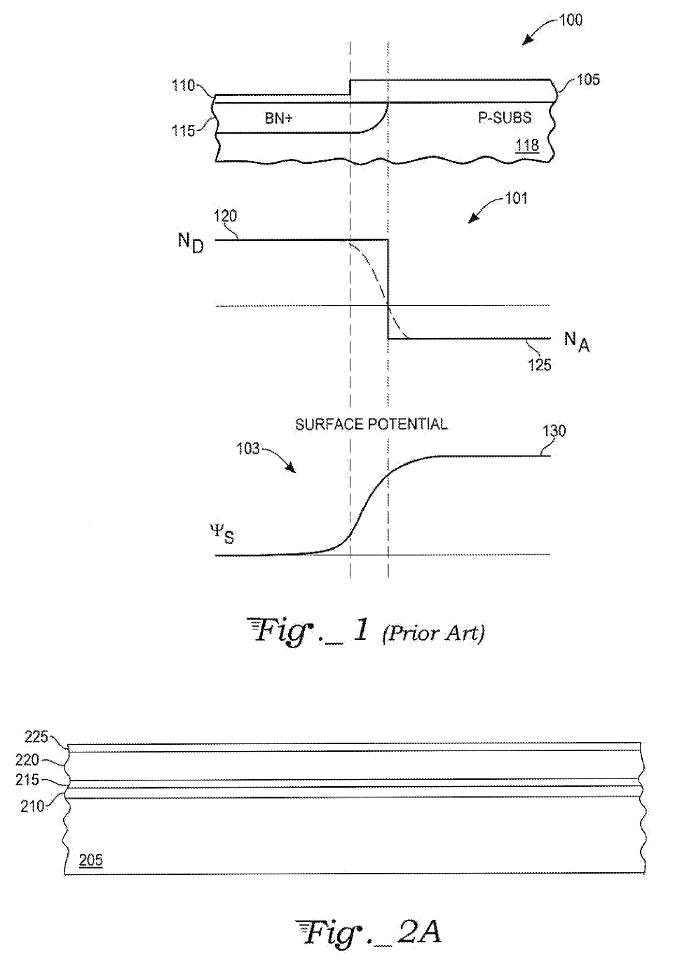

A surface potential diagram 403, corresponding to the semiconductor cross-section diagram 400, has a surface potential 430 (Ψ_{S}) commencing from a low level beneath the tunnel oxide window 410. The surface potential 430 continues laterally, corresponding to the substrate acceptor dopant 425 region, through a transition at the boundary of the buried n-type dopant layer 415 to a first surface potential corresponding to the surface of the p-type substrate 418. The surface potential 430 continues laterally, corresponding to the injector acceptor dopant 435 region, through a transition at the boundary of the buried n-type dopant layer 415 to a lower potential at the surface of the injector dopant region 440. The surface potential 430 is altered at the lateral interface with the injector dopant region 440 by a potential shift 445 (ΔΨ_{S}) compared to the surface potential of the acceptor dopant 125 beneath the tunnel oxide window 110 (FIG. 1). With the surface potential altered by the potential shift 445, electrons tunneling through the barrier require a lower potential energy difference compared with prior EEPROM cells. It would be clear to one of skill in the art that alternate embodiments of the above detailed description may exist. Therefore, the above description is illustrative and not restrictive. The scope of the invention should therefore be determined by reference to the appended claims and not by the above description.

What is claimed is:

1. A method of fabricating an electronic integrated circuit device on a first surface of a substrate, the method comprising:
forming a first dielectric film layer over the first surface of the substrate;
forming at least one further dielectric film layer over the first dielectric and creating a first aperture in the at least one further dielectric film layer, the first aperture having sidewalls that are non-parallel to the first surface of the substrate;
etching a portion of the first dielectric film layer underlying the first aperture to form a tunneling window;
creating a first dopant region formed substantially within an upper portion of the substrate underlying the first aperture;
forming spacers on the sidewalls of the first aperture such that a distance between spacers on opposing sidewalls of the first aperture is less than a limit of optical photolithography, the opposing spacers thus forming a second aperture; and
creating a second dopant region formed substantially within an upper portion of the substrate underlying the second aperture, the second dopant region being self-aligned with the second aperture.

2. The method of claim 1, wherein the first dielectric film layer is a first oxide layer.

3. The method of claim 1, wherein the at least one further dielectric film layer includes a first nitride layer, a second oxide layer, and a second nitride layer.

4. The method of claim 1, wherein the first or second dopant region is formed by ion implantation.

5. The method of claim 1, wherein the first or second dopant region is formed by diffusing a dopant species.

6. The method of claim 1, wherein the step of forming spacers on the sidewalls of the first aperture comprises:
forming a spacer dielectric film layer over the at least one further dielectric film layer and a portion of the first dielectric film layer underlying the first aperture; and
etching regions of the spacer dielectric film layer that are essentially parallel to the first surface of the substrate while leaving regions of the spacer dielectric film layer that are essentially perpendicular to the first surface of the substrate, thus creating spacers.

7. The method of claim 6, wherein the step of etching regions of the spacer dielectric film layer is performed by a reactive ion etch (RIE).

8. The method of claim 6, wherein the spacer dielectric film is chosen such that a chemical etching property of the spacer dielectric film layer is dissimilar to a chemical etching property of the first dielectric film.

9. The method of claim 1, wherein the substrate is substantially comprised of a p-type silicon wafer.

10. A method of fabricating an electronic integrated circuit device, comprising:
providing a substrate, the substrate being substantially comprised of silicon and having a first surface;
forming a first dielectric film layer over the first surface of the substrate;
forming at least one further dielectric film layer over the first dielectric film layer and creating a first aperture in the at least one further dielectric film layer, the first aperture having sidewalls that are non-parallel to the first surface of the substrate;
etching a portion of the first dielectric film layer underlying the first aperture thus forming a tunneling window;
creating a first dopant region formed substantially within an upper portion of the substrate underlying the first aperture;
forming a spacer film layer over the at least one further dielectric film layer and a portion of the first dielectric film layer underlying the first aperture;
etching regions of the spacer film layer that are essentially parallel to the first surface of the substrate while leaving regions of the spacer film layer that are essentially perpendicular to the first surface of the substrate, to create spacers on the sidewalls of the first aperture, a distance between spacers on opposing sidewalls of the first aperture being less than a limit of optical photolithography, a second aperture formed by the opposing spacers; and
creating a second dopant region formed substantially within a portion of the substrate underlying the second aperture and within the first dopant region, the second dopant region being self-aligned with the second aperture.

11. The method of claim 10, wherein the step of etching regions of the spacer film layer is performed by a reactive ion etch (RIE).

12. The method of claim 10, wherein the first dielectric film layer is chosen such that a chemical etching property of the dielectric material is dissimilar to a chemical etching property of the at least one further dielectric film.

13. The method of claim 10, wherein the silicon substrate is substantially comprised of a p-type silicon wafer.

14. The method of claim 10, wherein the first or second doped region is formed by ion implantation.

15. The method of claim 10, wherein the first or second doped region is formed by diffusing a dopant species.

16. A memory device, comprising:
a floating gate forming a portion of the memory device, the floating gate being comprised substantially of a first semiconducting material and being constructed over a substrate;
a gate dielectric material interposed between the floating gate and a first surface of the substrate;
a recess etched in an upper portion of the gate dielectric material to form a tunneling window;
a first dopant region formed in relationship to the tunneling window substantially within an upper portion of the substrate and underlying a portion of the floating gate;
a spacer region formed on the sidewalls of the first aperture such that a distance between spacers on opposing sidewalls of the first aperture is less than a limit of optical photolithography, the opposing spacers thus forming a second aperture; and
an injector dopant region disposed in close proximity to and self-aligned with the second aperture, the injector dopant region encompassed by the first dopant region.

17. The memory device of claim 16, wherein the gate dielectric material is comprised substantially of silicon dioxide.

18. The memory device of claim 16, wherein the substrate is comprised substantially of p-type silicon.

19. The memory device of claim 16, wherein the first dopant region and the injector dopant region are substantially comprised of a first and a second dopant material respectively, the first and second dopant materials being of complementary type dopant materials.

20. The storage device of claim 19, wherein the first dopant material is a high-concentration n-type dopant and the second dopant is a high-concentration p-type dopant.

21. The storage device of claim 16, wherein a related select device is fabricated with a select gate of a second semiconducting material and with a plurality of source/drain regions adjacent to the select gate, the select gate produced with a high concentration of a first dopant material and the plurality of source/drain regions produced with a high concentration of a second dopant material.
